(19) United States
(12) Patent Application Publication
(10) Pub. No.: US 2007/0057300 A1
(43) Pub. Date: Mar. 15, 2007

(54) SEMICONDUCTOR DEVICE

(75) Inventor: Shinichi Fukada, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/466,796

(22) Filed: Aug. 24, 2006

(30) Foreign Application Priority Data
Sep. 12, 2005 (JP) 2005-263631

(51) Int. Cl. H01L 29/94

(52) U.S. Cl. 257/295; 257/E27.104

(57) ABSTRACT

A semiconductor device includes a substrate, a first electrode provided above the substrate, a ferroelectric layer provided above the first electrode, a second electrode provided above the ferroelectric layer, and a dielectric side spacer that is provided above the first electrode and on a side surface of at least the ferroelectric layer.

### BACKGROUND

1. Technical Field

The present invention relates to semiconductor devices that include a first electrode, a ferroelectric layer, and a second electrode.

2. Related Art

A ferroelectric memory device (FeRAM) is a nonvolatile memory that is capable of high-speed operation at low voltages, and its memory cell can be composed with one transistor and one capacitor (1T/1C). Accordingly, ferroelectric memory devices can be integrated to the level of integration of DRAMs, and therefore are highly expected as large-capacity nonvolatile memories.

In order to form a ferroelectric capacitor having a stacked structure, a laminated body including a first electrode, a ferroelectric layer and a second electrode is etched in a batch, while changing the etching condition for each of the layers.

However, because the laminated body has a large film thickness, it is difficult to etch the laminated body in a batch. Also, because the first and second electrodes are generally composed of a material that is difficult to be etched, such as, platinum, iridium or the like, their etching control is difficult. Furthermore, the ferroelectric layer is generally composed of oxide materials, and therefore would likely be reduced by hydrogen. Examples of related art are described in Japanese laid-open patent applications JP-A-2002-359361 and JP-A-2002-298022.

### SUMMARY

In accordance with an advantage of some aspects of the present invention, it is possible to provide a semiconductor device having a ferroelectric layer that excels in dielectric property and ferroelectric characteristics, in which reduction of the ferroelectric layer can be effectively prevented.

A semiconductor device in accordance with a first embodiment of the invention includes a substrate, a first electrode provided above the substrate, a ferroelectric layer provided above the first electrode, a second electrode provided above the ferroelectric layer, and a dielectric side spacer that is provided above the first electrode and on a side surface of at least the ferroelectric layer.

According to the semiconductor device in accordance with the first embodiment of the invention, the ferroelectric layer can be effectively prevented from being reduced, and the ferroelectric layer that has excellent Dielectric property and ferroelectric characteristics can be provided.

In the semiconductor device in accordance with the first embodiment of the invention, the first electrode may include a first region and a second region having a film thickness smaller than a film thickness of the first region, the second region may be provided at an end section of the first region, and the side spacer may be provided above the second region.

In the semiconductor device in accordance with the first embodiment of the invention, the side spacer may be composed of a ferroelectric material.

A semiconductor device in accordance with a second embodiment of the invention includes a substrate, a laminated body including a first electrode provided above the substrate, a ferroelectric layer provided above the first electrode and a second electrode provided above the ferroelectric layer, and a side spacer composed of a ferroelectric film that is provided on a side surface of the laminated body.

According to the semiconductor device in accordance with the second embodiment of the invention, the ferroelectric layer can be effectively prevented from being reduced, and the ferroelectric layer that has excellent dielectric property and ferroelectric characteristics can be provided.

In the semiconductor devices in accordance with the first and second embodiments of the invention, the ferroelectric layer and the side spacer may be composed of the same material. With this structure, reduction of the ferroelectric layer can be more effectively prevented, and changes in the characteristics of the ferroelectric layer can be prevented.

### BRIEF DESCRIPTION OF THE DRAWINGS

FIG. 1 schematically shows a cross-sectional view of a semiconductor device in accordance with a first embodiment of the invention.

FIG. 2 schematically shows a cross-sectional view of an area near a ferroelectric capacitor of the semiconductor device shown in FIG. 1.

FIGS. 3A-3E are cross-sectional views schematically showing steps of a method for manufacturing the semiconductor device shown in FIG. 1.

FIG. 4 schematically shows a cross-sectional view of a semiconductor device in accordance with a second embodiment of the invention.

FIG. 5 schematically shows a cross-sectional view of an area near a ferroelectric capacitor of the semiconductor device shown in FIG. 4.

FIGS. 6A-6E are cross-sectional views schematically showing steps of a method for manufacturing the semiconductor device shown in FIG. 4.

FIG. 7 schematically shows a cross-sectional view of a semiconductor device in accordance with a third embodiment of the invention.

FIGS. 8A-8E are cross-sectional views schematically showing steps of a method for manufacturing the semiconductor device shown in FIG. 7.

### DESCRIPTION OF EXEMPLARY EMBODIMENTS

Preferred embodiments of the invention are described below with reference to the accompanying drawings.

### 1. First Embodiment

1.1. Semiconductor Device

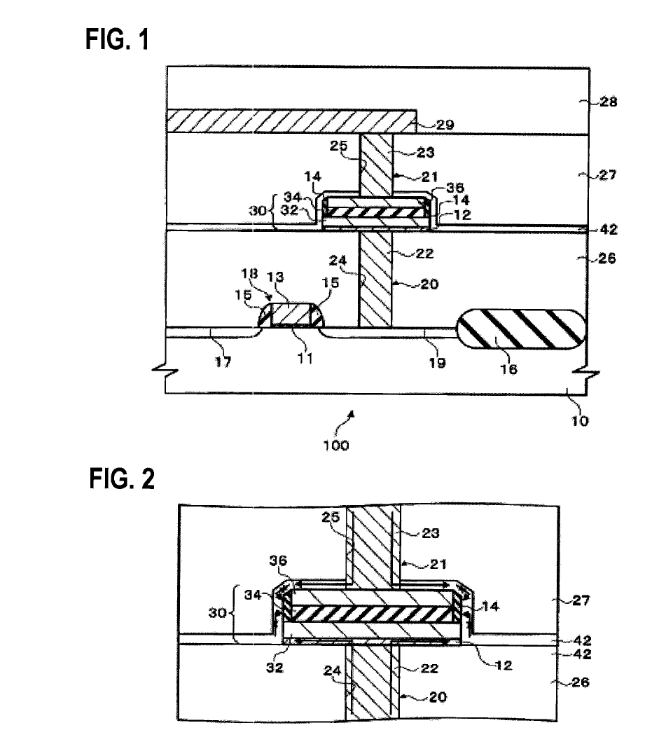

FIG. 1 schematically shows a cross-sectional view of a semiconductor device (e.g., a ferroelectric memory device) 100 in accordance with a first embodiment of the invention. As shown in FIG. 1, the semiconductor device 100 includes a ferroelectric capacitor 30, a plug 20, and a switching transistor 18 for the ferroelectric capacitor 30. It is noted that, although the present embodiment is described with reference to a 1T/1C type memory cell, the applicability of the invention is not limited to a 1T/1C type memory cell.

The transistor 18 includes a gate dielectric layer 11, a gate conductive layer 13 provided on the gate dielectric layer 11, and first and second impurity regions 17 and 19 that define source/drain regions. Also, a plug 20 is electrically connected to the switching transistor 18.

The ferroelectric capacitor 30 includes a first barrier layer 12, a first electrode 32 provided above the first barrier layer 12, a ferroelectric layer 34 provided above the first electrode 32, and a second electrode 36 provided above the ferroelectric layer 34.

Also, the semiconductor device 100 in accordance with the present embodiment further includes a dielectric side spacer 14. The side spacer 14 may be provided above the first electrode 32, and on a side surface of at least the ferroelectric layer 34. In the semiconductor device 100 in accordance with the present embodiment, the side spacer 14 is provided, as shown in FIG. 1, above the first electrode 32, and on side surfaces of the ferroelectric layer 34 and the second electrode 36.

In other words, as shown in FIG. 1, because the laminated body of the ferroelectric layer 34 and the second electrode 36 as well as the side spacer 14 are provided on the first electrode 32, a lateral cross sectional width of the ferroelectric layer 34 and the second electrode 36 is smaller than a lateral cross sectional width of the first electrode 32. Also, a lateral cross sectional width of the first electrode 32 is generally equal to the sum of a lateral cross sectional width of the side spacer 14 and a lateral cross sectional width of the ferroelectric layer 34 (or the second electrode 36).

Also, the ferroelectric capacitor 30 is provided on the plug 20 that is provided in a dielectric layer 26. The plug 20 is formed on the second impurity region 19. The dielectric layer 26 has an opening section 24, and the plug 20 includes a plug conductive layer 22 provided in the opening section 24. The plug conductive layer 22 is composed of a high melting point metal, such as, for example, tungsten, molybdenum, tantalum, titanium, nickel or the like, and may preferably be composed of tungsten.

The first barrier layer 12 has at least a portion provided on the plug 20. The first barrier layer 12 is provided to prevent oxidation of the plug 20. The first barrier layer 12 may be composed of any material that has conductivity and oxygen barrier capability without any particular limitation.

As the first barrier layer 12, for example, TiAlN, TiAl, TiSiN, TiN, TaN, and TaSiN may be enumerated. Above all, the barrier layer 14 may preferably be composed of a layer that includes titanium, aluminum and nitrogen (e.g., TiAlN).

When the first barrier layer 12 is composed of TiAlN, and the composition (atom ratio) of titanium, aluminum and nitrogen in the first barrier layer 12 is expressed by a chemical formula of Ti₍₁₋ₓ₎AlₓN_{y}, in a preferred embodiment, x may be in a range of 0<x≦0.5, and y may be greater than 0 (0<y).

The first electrode 32 may be composed of at least one kind of metal selected from platinum, ruthenium, rhodium, palladium, osmium and iridium, may preferably be composed of platinum or iridium, and may more preferably be composed of iridium. Also, the first electrode 32 may be composed of a single layer film, or a multilayer film of laminated layers.

The ferroelectric layer 34 includes a ferroelectric material. The ferroelectric material has a perovskite crystal structure and may be expressed by a general formula of A B₁₋ₐXₐO₃. It is noted here that A is composed of an element such as Pb, Ca, Sr or La, and B and X are each composed of an element such as Ti, Zr, Nb or Mg. Pb Ti₁₋ₐZrₐO₃ (PZT) is a typical material as the ferroelectric material, and a very small amount of additive elements may be added to this basic composition. Also, SrBi₂Ta₂O₉ (SBT) or (Bi, La)₄Ti₃O₁₂ (BLT), which has a crystal structure derived from a perovskite type crystal structure, can be used as the aforementioned ferroelectric material.

Among the materials listed above, PZT is suitable as the material of the ferroelectric layer 34. In this case, the first electrode 32 may preferably be composed of iridium from the viewpoint of device reliability. When PZT is used as the material of the ferroelectric layer 34, the content of titanium in the PZT may preferably be greater than the content of zirconium in order to obtain a greater amount of spontaneous polarization.

The second electrode 36 may be composed of any of the materials described above as an example of the material that can be used as the first electrode 32, or may be composed of aluminum, silver, nickel or the like. Also, the second electrode 36 may be in a single layer film, or a multilayer film of laminated layers. The second electrode 36 may preferably be composed of platinum or a laminated film of layers of iridium oxide and iridium.

In the semiconductor device 100 in accordance with the present embodiment, a second barrier layer 42 is provided in a manner that the second barrier layer 42 covers the side surface and upper surface of the ferroelectric capacitor 30, as shown in FIG. 1. The second barrier layer 42 may preferably be composed of a material having hydrogen barrier capability in order to prevent reduction of the ferroelectric layer 34. The second barrier layer 42 may be composed of, for example, alumina or p-TEOS.

Furthermore, a dielectric layer 27 is provided on the second barrier layer 42, and a plug 21 that penetrates the dielectric layer 27 and the second barrier layer 42 is provided on the ferroelectric capacitor 30. The dielectric layer 27 includes an opening section 25, and the plug 21 includes a plug conductive layer 23 provided in the opening section 25. The plug conductive layer 23 may be composed of one of those materials exemplified as the material of the plug conductive layer 22. Also, a wiring layer 29 is provided on the plug 23 and the dielectric layer 27, and a dielectric layer 28 is provided on the wiring layer 29.

FIG. 2 is a schematic cross-sectional view of a section near the ferroelectric capacitor 30 shown in FIG. 1. It is noted that the ferroelectric layer included in the ferroelectric capacitor is generally composed of oxide materials, and therefore would likely be reduced. As the ferroelectric layer is reduced, this would cause problems in that the dielectric property and ferroelectric characteristics would deteriorate. Hydrogen is one of the materials that cause reduction of the ferroelectric layer. Accordingly, ferroelectric capacitors are generally required to prevent penetration of hydrogen.

Arrows in FIG. 2 indicate routes of hydrogen penetration in the ferroelectric capacitor 30 shown in FIG. 1. More concretely, as shown in FIG. 2, hydrogen would penetrate into the side spacer 14 through an interface between the plug 21 and the dielectric layer 27 and an interface between the second barrier layer 42 and the second electrode 36, and/or through an interface between the plug 22 and the first barrier layer 12 and an interface between the second barrier layer 42 and the first electrode 32. If hydrogen penetrates into the ferroelectric layer 34, the ferroelectric layer 34 would be reduced by the hydrogen, and its dielectric property and ferroelectric characteristics are lowed, which are undesirable.

In contrast, in the semiconductor device 100 in accordance with the present embodiment, the side spacer 14 is provided above the first electrode 32, and on the side surface of the ferroelectric layer 34, whereby hydrogen can be prevented from penetrating into the ferroelectric layer 34.

The side spacer 14 may be composed of any insulating material without any particular limitation, and may be composed of a dielectric material, such as, for example, alumina, p-TEOS or the like, and a ferroelectric material. Above all, the side spacer 14 may preferably be composed of a ferroelectric material. When the side spacer 14 is composed of a ferroelectric material, hydrogen can be caught by the ferroelectric material, and effectively prevented from penetrating into the ferroelectric layer 34, and furthermore, Qsw and retention characteristic of the ferroelectric capacitor 30 that is to be finally obtained can be maintained. In this case, the side spacer 14 would more preferably be composed of the same material as that of the ferroelectric layer 34. When the side spacer 14 is composed of the same material as that of the ferroelectric layer 34, reduction of the ferroelectric layer 34 can be more effectively prevented, and the characteristics of the ferroelectric layer 34 would not be changed by the side spacer 14.

According to the semiconductor device 100 in accordance with the present embodiment, because the dielectric side spacer 14 is provided above the first electrode 32, and on at least the side surface of the ferroelectric layer 34, reduction of the ferroelectric layer 34 can be effectively prevented. Also, because the side spacer 14 is provided, insulation between the first electrode 32 and the second electrode 36 can be secured.

Also, as described below in a later section concerning a manufacturing method, because the semiconductor device 100 in accordance with the present embodiment has the dielectric side spacer 14 provided above the first electrode 32 and on the side surface of at least the ferroelectric layer 34, the ferroelectric layer 34 can be prevented from being exposed to active chemical species, and conductive materials can be prevented from adhering to the side surface of the ferroelectric layer 34, when the first electrode 32 (and the first barrier layer 12) is etched. By this, the semiconductor device 100 in accordance with the present embodiment has the ferroelectric layer 34 that excels in dielectric property and ferroelectric characteristic. In addition, because adhesion of conductive materials to the side surface of the ferroelectric layer 34 can be prevented, the entire area of the ferroelectric layer 34 can be functioned as a capacitor. As a result, the ferroelectric capacitor 30 can secure a predetermined amount of charge with an effectively smaller area, and therefore the ferroelectric capacitor 30 can be further miniaturized.

In particular, the side spacer 14 may have a configuration that becomes smaller toward its upper end section (upwardly convex configuration). Because of this configuration, conductive materials would not adhere to the side spacer 14 when the first electrode 32 (and the first barrier layer 12) is etched.

Furthermore, as described below in a later section concerning a manufacturing method, because the semiconductor device 100 in accordance with the present embodiment has a structure in which the dielectric side spacer 14 provided above the first electrode 32 and on the side surface of at least the ferroelectric layer 34, the structure can prevent occurrence of a phenomenon in which exfoliation of films at an interface between the first electrode 32 and the ferroelectric layer 34 or an interface between the ferroelectric layer 34 and the second electrode 36 occurs and portions above the interface are blown away, when the first electrode 32 (or the first barrier layer 12) is etched.

1-2. Method for Manufacturing Semiconductor Device

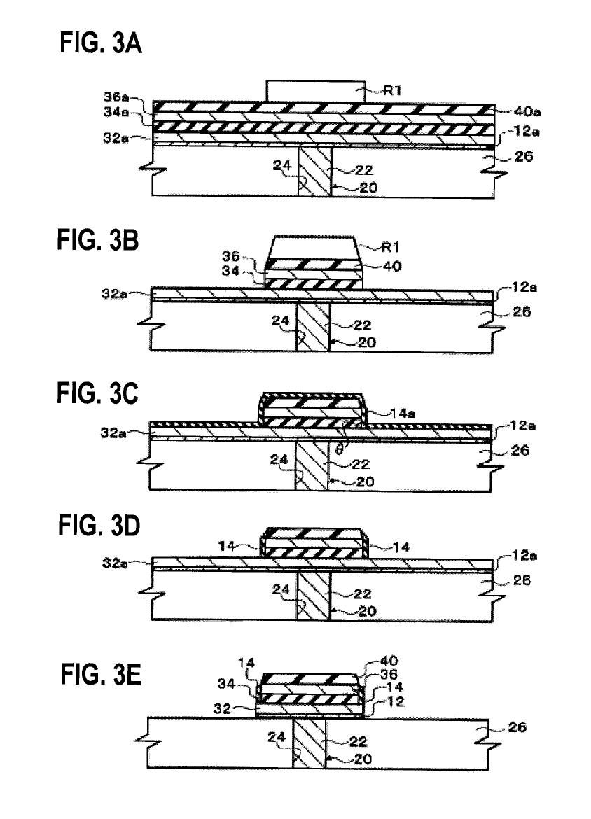

Next, an example of a method for manufacturing a semiconductor device 100 shown in FIG. 1 is described with reference to the accompanying drawings. FIGS. 3A through 3E are cross-sectional views schematically showing steps of a process for manufacturing the semiconductor device 100 shown in FIG. 1. It is noted that FIGS. 3A through 3E show only a neighboring area of a dielectric layer 26 and a plug 20 in the semiconductor device 100 shown in FIG. 1.

First, a transistor 18 and a plug 20 are formed (see FIG. 1). More concretely, the transistor 18 is formed on a semiconductor substrate 10, and then a dielectric layer 26 is laminated over the transistor 18. Next, an opening section 24 is formed in the dielectric layer 26 by, for example, a dry etching method, and the opening section 24 is embedded with a plug conductive layer 22, thereby forming the plug 20. The plug conductive layer 22 may be embedded by, for example, a CVD method or a sputter method. Then, portions of the plug conductive layer 22 deposited on the upper surface of the dielectric layer 26 are removed by, for example, mechanical chemical polishing, thereby forming the plug 20.

Then, a ferroelectric capacitor 30 is formed (see FIG. 3A-FIG. 3E).

First, as shown in FIG. 3A, a first barrier layer 12a, a first electrode 32a, a ferroelectric layer 34a, a second electrode 36a and a hard mask layer 40a are sequentially formed above the substrate 10 (more concretely, on the dielectric layer 26 and the plug 20). Then, a resist layer R1 having a predetermined pattern is formed on the hard mask layer 40a. The film thickness of the hard mask layer 40a is not particularly limited, but may preferably be less than 100 nm, and more preferably be 50-100 nm. Also, the film thickness of the first electrode 32a is not particularly limited, but may preferably be, for example, 100-150 nm.

As a film forming method for forming the first barrier layer 12a, the first electrode 32a and the second electrode 36a, for example, a sputter method and a CVD method may be enumerated. Also, the ferroelectric layer 34a and the hard mask layer 40a may be formed by any one of suitable film forming methods selected according to the material used therein, and may be formed by, for example, a spin-on method, a sputter method, a MOCVD method or the like.

Then, as shown in FIG. 3B, by using the resist layer R1 as a mask, the hard mask layer 40a is patterned by a photolithography method. By this, a hard mask layer 40 is obtained. Then, by using the hard mask layer 40 as a mask, the second electrode 36a and the ferroelectric layer 34a are etched, thereby obtaining a second electrode 36 and a ferroelectric layer 34. Then, the resist layer R1 is removed.

It is noted that, in order to form a dielectric film 14a having a film thickness sufficient to form a side spacer 14 in a process to be described below, the ferroelectric layer 34 may preferably be etched in a manner that the ferroelectric layer 34 has a taper angle (an angle defined between the side surface of the ferroelectric layer 34 and the top surface of the first electrode 32a in FIG. 3C) θ that is greater than 75°.

Then, as shown in FIG. 3C, a dielectric film (e.g., a ferroelectric film) 14a is formed on the first electrode 32a and a laminated body of the ferroelectric layer 34, the second electrode 36 and the hard mask layer 40. It is noted that the dielectric film 14a may be formed by any one of suitable film forming methods without any particular limitation, but may preferably be formed by a MOCVD method. By forming the dielectric film 14a by a MOCVD method, the dielectric film 14a can be uniformly formed along the surface of the first electrode 32a and the surface of the laminated body of the ferroelectric layer 34, the second electrode 36 and the hard mask layer 40.

Then, as shown in FIG. 3D, the dielectric film 14a is anisotropically etched, thereby obtaining a side spacer 14.

Then, as shown in FIG. 3E, exposed portions of the first electrode 32a and the first barrier layer 12 are etched. It is noted that, because the side spacer 14 is provided on the side surface of the ferroelectric layer 34, the side surface of the ferroelectric layer 34 can be prevented from being exposed to active chemical species such as plasma charge, charge particles, radicals and the like, when the first electrode 32a and the first barrier layer 12a are etched, whereby dielectric property and ferroelectric characteristic of the ferroelectric layer 34 can be prevented from lowering. Also, because the side spacer 14 is provided on the side surface of the ferroelectric layer 34, conductive materials, which are generated by etching at the time of etching the first electrode 32 or the first barrier layer 12, can be prevented from being adhered to the side surface of the ferroelectric layer 34. In this respect also, dielectric property and ferroelectric characteristics of the ferroelectric layer 34 can be prevented from lowering.

On the other hand, the side spacer 14 does not contribute to the capacitor characteristics of the ferroelectric capacitor 30. Therefore, exposure of the surface of the side spacer 14 to active chemical species or adhesion of some conductive materials to the side spacer 14 would not influence the capacitor characteristics of the ferroelectric capacitor 30. Furthermore, even if the surface of the side spacer 14 is damaged, or conductive materials are adhered to the surface of the side spacer 14, the damages and the conductive materials can be removed by etching the surface of the side spacer 14.

Also, adhesion between the first and second electrodes 32 and 36 and the ferroelectric layer 34 is not generally very high. As a result, a phenomenon called “capacitor blow-out” may occur. In this phenomenon, exfoliation of films at an interface between the first electrode 32 and the ferroelectric layer 34 or an interface between the ferroelectric layer 34 and the second electrode 36 occurs and portions above the interface are blown away. In particular, when the ferroelectric layer 34 is formed by a MOCVD method, adhesion at the interfaces is low, and capacitor blow-out phenomena frequently occur.

In contrast, because the semiconductor device 100 in accordance with the present embodiment has the side spacer 14 provided on the first electrode 32 and on the side surface of the ferroelectric layer 34, the side spacer 14 functions to prevent exfoliation at an interface between the first electrode 32 and the ferroelectric layer 34 or at an interface between the ferroelectric layer 34 and the second electrode 36. By this, occurrence of capacitor blow-out phenomena can be prevented. In particular, when the ferroelectric layer 34 is formed by a MOSVD method, capacitor blow-out phenomena can be effectively prevented.

After removing the hard mask layer 40, deposits (for example, conductive materials generated at the time of etching the first electrode 32a and the first barrier layer 12) adhered to the surface of the side spacer 14 are removed by etching. By this step, the first electrode 32 and the second electrode 36 are securely insulated from each other. Then, a second barrier layer 42 and a dielectric layer 27 are laminated, and then a plug 21 is formed by a method similar to the method applied to the plug 20. By the steps described above, the semiconductor device 100 including the stacked type ferroelectric capacitor 30 is obtained (see FIG. 1).

### 2. Second Embodiment

2-1. Semiconductor Device

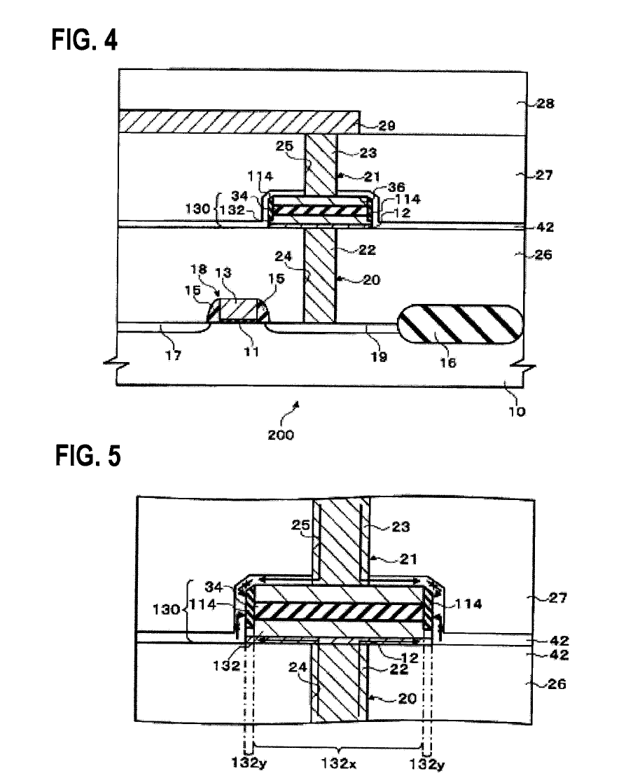

FIG. 4 schematically shows a cross-sectional view of a semiconductor device (ferroelectric memory device) 200 in accordance with another embodiment of the invention. The semiconductor device 200 in accordance with the present embodiment has a structure similar to the structure of the semiconductor device 100 in accordance with the first embodiment described above except that a first electrode 132 includes a first region 132x and a second region 132y having a film thickness smaller than that of the first region 132x. Accordingly, detailed descriptions of components of the semiconductor device 200 of the present embodiment similar to those of the semiconductor device 100 of the first embodiment described above are omitted.

FIG. 5 is a cross-sectional view schematically showing an area near a ferroelectric capacitor 130 shown in FIG. 4. In the semiconductor device 200 of the present embodiment, the second region 132y of the first electrode 132 is provided at an end section of the first region 132x, as shown in FIG. 5. A lateral cross-sectional width of the first region 132x of the first electrode 132 is generally equal to a lateral cross-sectional width of a ferroelectric layer 34 and a second electrode 36, as shown in FIG. 5. It is noted that the first electrode 132 may be composed of a material similar to that of the first electrode 32 of the semiconductor device 100 in accordance with the first embodiment described above.

Also, in the semiconductor device 200 in accordance with the present embodiment, a side spacer 114 is provided on the second region 132y. The side spacer 114 may be composed of a material similar to that of the side spacer 14 of the semiconductor device 100 in accordance with the first embodiment. As shown in FIG. 5, a lateral cross-sectional width of the second region 132y of the first electrode 132 is generally equal to a lateral cross-sectional width of the side spacer 114.

The semiconductor device 200 in accordance with the present embodiment has actions and effects similar to those of the semiconductor device 100 in accordance with the first embodiment described above. Further, in the semiconductor device 200 in accordance with the present embodiment, the first electrode 132 has the first region 132x and the second region 132y having a film thickness smaller than that of the first region 132x, the second region 132y is provided at an end section of the first region 132x, and the side spacer 114 is provided on the second region 132y. In other words, the side spacer 114 is provided on an upper surface of the first electrode 132 (on the second region 132y) and on the side surface thereof. By this, “capacitor blow-out” phenomena can be more effectively suppressed.

2-2. Method for Manufacturing Semiconductor Device

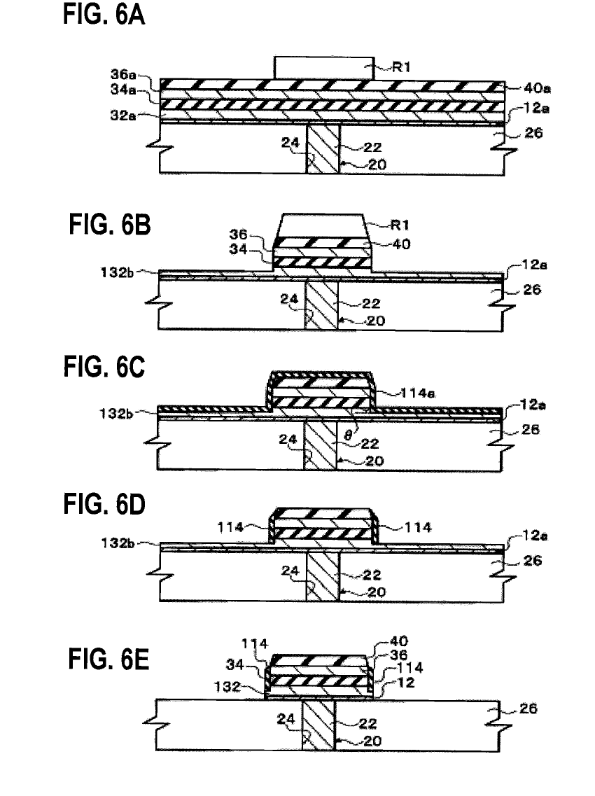

Next, an example of a method for manufacturing the semiconductor device 200 shown in FIG. 4 is described with reference to the accompanying drawings. FIGS. 6A through 6E are cross-sectional views schematically showing steps of a process for manufacturing the semiconductor device 200 shown in FIG. 4. It is noted that FIGS. 6A through 6E show only a neighboring area of a dielectric layer 26 and a plug 20 in the semiconductor device 200 shown in FIG. 4. It is noted that detailed descriptions of steps included in the method for manufacturing the semiconductor device 200 in accordance with the present embodiment similar to those of the method for manufacturing the semiconductor device 100 in accordance with the first embodiment described above are omitted.

In the method for manufacturing the semiconductor device 200 in accordance with the present embodiment, when a second electrode 36a and a ferroelectric layer 34a are etched, etching is conducted up to an intermediate point of the first electrode 32a, as shown in FIG. 6B. Then, a dielectric film 114a is formed in a manner similar to the dielectric film 14a of the semiconductor device 100 of the first embodiment (see FIG. 6C), a side spacer 114 is formed by a method similar to the method for manufacturing the semiconductor device 100 of the first embodiment (see FIG. 6D), and the first electrode 32a and the first barrier layer 12a are patterned (see FIG. 6E). As a result, a first electrode 132 including a first region 132× and a second region 132y can be formed (see FIG. 6E). Succeeding manufacturing steps are similar to those applied to the semiconductor device 100 in accordance with the first embodiment.

The method for manufacturing the semiconductor device 200 in accordance with the present embodiment exhibits actions and effects similar to those achieved by the method for manufacturing the semiconductor device 100 in accordance with the first embodiment described above, and therefore their detailed description is omitted.

### 3. Third Embodiment

3-1. Semiconductor Device

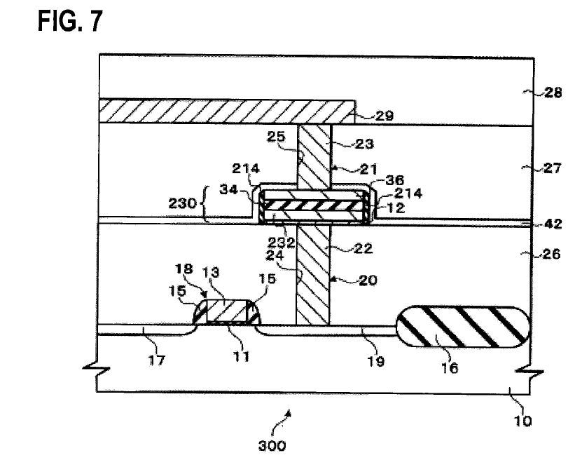

FIG. 7 schematically shows a cross-sectional view of a semiconductor device (ferroelectric memory device) 300 in accordance with still another embodiment of the invention. The semiconductor device 300 in accordance with the present embodiment has a structure similar to those of the semiconductor devices 100 and 200 in accordance with the first and second embodiments described above except that a side spacer 214 is provided on side surfaces of a first electrode 232, a ferroelectric layer 34 and a second electrode 36. Accordingly, detailed descriptions of components of the semiconductor device 300 of the present embodiment similar to those of the semiconductor devices 100 and 200 of the first and second embodiments described above are omitted.

The semiconductor device 300 in accordance with the present embodiment includes a substrate 10, a laminated body (ferroelectric capacitor) 230, and a side spacer 214 composed of a ferroelectric film which is provided on a side surface of the laminated body 230. The laminated body (ferroelectric capacitor) 230 includes a first electrode 232 provided above the substrate 10, a ferroelectric layer 34 provided above the first electrode 232, and a second electrode 36 provided above the ferroelectric layer 34. The first electrode 232 may be composed of a material similar to that of the first electrode 32 of the semiconductor device 100 of the first embodiment described above. Also, the side spacer 214 may preferably be composed of the same material as that of the ferroelectric layer 34.

The semiconductor device 300 in accordance with the present embodiment has actions and effects similar to those of the semiconductor devices 100 and 200 in accordance with the first and second embodiments described above.

3-2. Method for Manufacturing Semiconductor Device

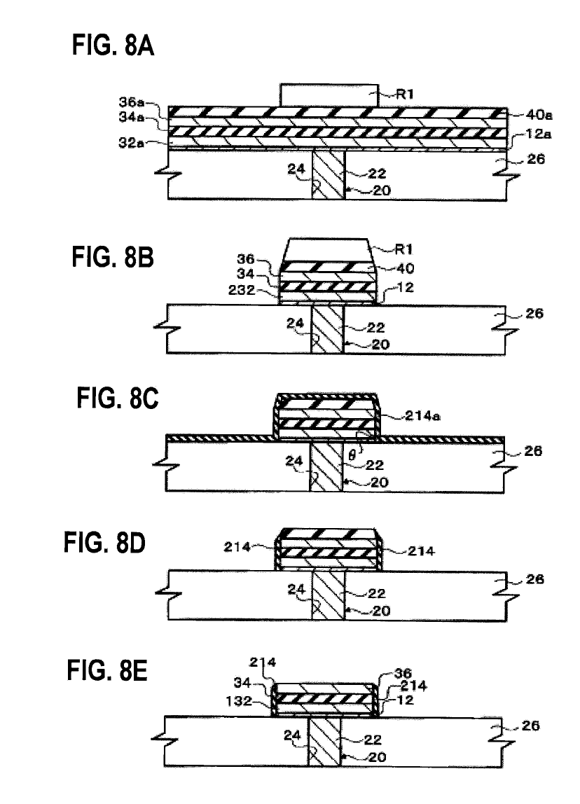

Next, an example of a method for manufacturing the semiconductor device 300 shown in FIG. 7 is described with reference to the accompanying drawings. FIGS. 8A through 8E are cross-sectional views schematically showing steps of a process for manufacturing the semiconductor device 300 shown in FIG. 7. It is noted that FIGS. 8A through 8E show only a neighboring area of a dielectric layer 26 and a plug 20 in the semiconductor device 300 shown in FIG. 7. It is noted that detailed descriptions of steps included in the method for manufacturing the semiconductor device 300 in accordance with the present embodiment similar to those of the method for manufacturing the semiconductor device 100 in accordance with the first embodiment described above are omitted.

In the method for manufacturing the semiconductor device 300 in accordance with the present embodiment, as shown in FIG. 8B, a first electrode 32a and a first barrier layer 12a are etched together with a second electrode 36a and a ferroelectric layer 34a, thereby forming a first barrier layer 12, a first electrode 232, a ferroelectric layer 34 and a second electrode 36. Then, a dielectric film 214a is formed in a manner similar to the dielectric film 14a of the semiconductor device 100 of the first embodiment (see FIG. 8C), a side spacer 214 is formed by a method similar to the manufacturing method applied to the semiconductor device 100 of the first embodiment (see FIG. 8D), and then a hard mask layer 40 is removed (see FIG. 8E). Succeeding manufacturing steps are similar to those applied to the semiconductor device 100 in accordance with the first embodiment.

The method for manufacturing the semiconductor device 300 in accordance with the present embodiment exhibits actions and effects similar to those achieved by the method for manufacturing the semiconductor devices 100 and 200 in accordance with the first and second embodiments described above, and therefore their detailed description is omitted.

The preferred embodiments of the invention are described above in detail. However, those skilled in the art should readily understand that many modifications can be made without departing in substance from the novel matter and effects of the invention. Accordingly, those modified examples are also included in the scope of the invention.

For example, the ferroelectric capacitors and the methods for manufacturing the same in accordance with the embodiments of the invention are applicable to, for example, capacitors included in piezoelectric elements and the like.

What is claimed is:

1. A semiconductor device comprising:
a substrate;
a first electrode provided above the substrate;
a ferroelectric layer provided above the first electrode;
a second electrode provided above the ferroelectric layer; and
a dielectric side spacer that is provided above the first electrode and on a side surface of at least the ferroelectric layer.

2. A semiconductor device according to claim 1, wherein the first electrode includes a first region and a second region having a film thickness smaller than a film thickness of the first region, the second region is provided at an end section of the first region, and the side spacer is provided above the second region.

3. A semiconductor device according to claim 1, wherein the side spacer is composed of a ferroelectric material.

4. A semiconductor device comprising:
a substrate;
a laminated body including a first electrode provided above the substrate, a ferroelectric layer provided above the first electrode and a second electrode provided above the ferroelectric layer; and
a side spacer composed of a ferroelectric film that is provided on a side surface of the laminated body.

5. A semiconductor device according to claim 1, wherein the ferroelectric layer and the side spacer are composed of an identical material.
